(19) United States
(12) Patent Application Publication
(10) Pub. No.: US 2011/0177665 A1
(43) Pub. Date: Jul. 21, 2011

(54) THERMAL PROCESS

(76) Inventors: Chan-Lon Yang, Taipei City (TW); Ching-I Li, Tainan County (TW); Tzu-Feng Kuo, Hsinchu City (TW)

(21) Appl. No.: 12/691,723

(22) Filed: Jan. 21, 2010

(51) Int. Cl. H01L 21/336; H01L 21/26

(52) U.S. Cl. 438/306; 438/795; 257/E21.328; 257/E21.437

(57) ABSTRACT

A thermal process is disclosed. The thermal process preferably includes the steps of: providing a semiconductor substrate ready to be heated; and utilizing at least a first heating beam and a second heating beam with different energy density to heat the semiconductor substrate simultaneously. Accordingly, the present invention no only eliminates the need of switching between two different thermal processing equipments and shortens the overall fabrication cycle time, but also improves the pattern effect caused by the conventional front side heating.

### BACKGROUND OF THE INVENTION

1. Field of the Invention

The invention relates to a thermal process, and more particularly, to a thermal process of using at least two heating beams with different energy density to heat a semiconductor substrate simultaneously.

2. Description of the Prior Art

With the advancing technology of the semiconductor industry, integrated circuits (ICs) are being developed to increase the current computing and storage capability, which pushes the development of related manufacturers forward. As predicted by Moore's law, the number of transistors doubles every 18 months. The process of semiconductor evolves from 0.18 nm of 1999, 0.13 μm of 2001, 90 nm of 2003 to 65 nm of 2005 and is approaching 45 nm. Therefore, the density of semiconductor elements on a wafer is increasing with the technology advancement of the semiconductor industry and miniaturization of microelectronic elements and makes the intervals between elements shorter and shorter. Under this situation, many semiconductor fabrication processes face new challenges and bottlenecks, and therefore the manufacturers have to keep on researching new fabrication technologies to meet the request of high integration.

Among various semiconductor fabrication processes, the rapid thermal process (RTP) is a very important technology and has been widely applied to the thermal activating of semiconductor processes in the fabrication of very large scale integration (VLSI) field. Its application may contain the formation of the ultra shallow junction (USJ) of metal-oxide-semiconductor (MOS) transistors, ultra thin oxide layer growth, annealing, diffusion, formation of metal silicide, and even the semiconductor layer of thin film transistors. With the advancing technology of the semiconductor industry, rapid thermal processes are being developed to meet the requirements of high fabrication grades. According to the development of thermal processes, high-temperature furnace is a representative tool in earlier technology, and the spike rapid thermal annealing is utilized for rapid thermal treatment in the 90 nm grade process. Currently, as the semiconductor technology is developed to the 65 nm grad process, new rapid thermal processes, such as flash/non-melt annealing, impulse and laser annealing, are researched to be applied. Correspondingly, the process time of a thermal process also becomes shorter and shorter. For example, the process time is about 10 sec for the earlier furnace process, and the process time is shortened to about 1 sec or even about 1 msec (millisecond) for the current thermal process.

Nevertheless, the aforementioned rapid thermal processes, including the ones carried out with high temperature furnace or millisecond anneal process, still cause numerous problems. For instance, a rapid thermal process conducted with high temperature furnace and a millisecond anneal process conducted through laser involve two different types of equipment, hence if a MOS transistor process were to use these two thermal processes, a wafer has to be treated on an equipment for either one of the thermal process before moving to another equipment for another thermal process. The switch between equipments not only consumes a great deal of time, but also extends the cycle time of the overall fabrication.

Moreover, in a typical MOS transistor fabrication, the front surface of the semiconductor substrate is often heated directly after ion implantations to diffuse implanted ions into doping regions. However, when the surrounding of the semiconductor substrate of the transistor region is replaced by other non-silicon structure, such as shallow trench isolations (STIs) or other films are disposed on the semiconductor substrate, the thermal absorption capability of the doping regions is affected substantially during the thermal treatment process and results in a pattern effect.

### SUMMARY OF THE INVENTION

It is an objective of the present invention to provide a thermal process on a semiconductor substrate to resolve the aforementioned issues caused by conventional thermal process.

According to a preferred embodiment of the present invention, a thermal process is disclosed. The thermal process preferably includes the steps of: providing a semiconductor substrate ready to be heated; and utilizing at least a first heating beam and a second heating beam with different energy density to heat the semiconductor substrate simultaneously. Accordingly, the present invention no only eliminates the need of switching between two different thermal processing equipments and shortens the overall fabrication cycle time, but also improves the patterning effect caused by the conventional front side heating substantially.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a perspective view of performing a thermal process on a semiconductor substrate according to a first embodiment of the present invention.

FIG. 2 illustrates a perspective view of a MOS transistor region of the semiconductor substrate.

FIG. 3 illustrates the spots generated by two heating beams heating the surface of the semiconductor substrate simultaneously and a relational diagram between temperature and time.

FIG. 4 illustrates a perspective view of performing a thermal process on a semiconductor substrate according to a second embodiment of the present invention.

FIG. 5 illustrates a perspective view of a MOS transistor region of the semiconductor substrate.

### DETAILED DESCRIPTION

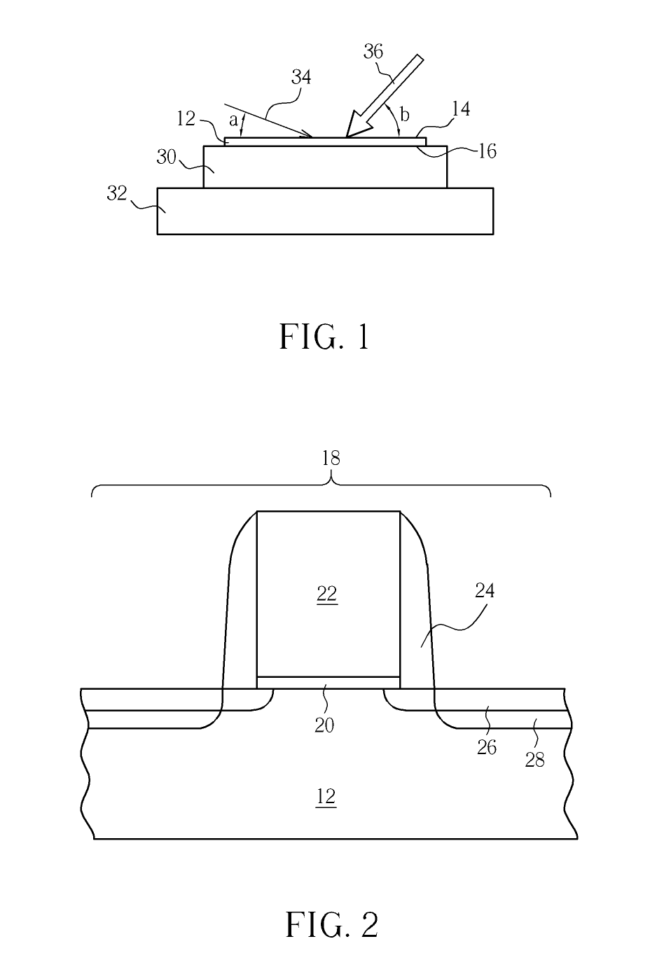

Referring to FIGS. 1-2, FIG. 1 illustrates a perspective view of performing a thermal process on a semiconductor substrate according to a first embodiment of the present invention, and FIG. 2 illustrates a perspective view of a MOS transistor region of the semiconductor substrate. As shown in the figures, a semiconductor substrate 12, such as a silicon wafer ready to be heated is provided. The semiconductor substrate 12 has a front surface 14 and a back surface 16, in which a MOS transistor region 18 is defined on the front surface 14. Structures including a gate dielectric layer 20, a gate 22, and a spacer 24 are preferably formed on the front surface 14 of the semiconductor substrate 12. Moreover, at least one ion implantation is conducted to form a source/drain extension doping region (not shown) adjacent to two sides of the gate 22 in the semiconductor substrate 12 or a source/drain doping region (not shown) adjacent to two sides of the spacer 24 in the semiconductor substrate 12.

The semiconductor substrate 12 is then placed on a scanning apparatus 30, which is preferably situated on top of a supporting stage 32. After turning on the scanning apparatus 30 and putting the semiconductor substrate 12 in motion, a thermal processing equipment (not shown), such as a laser generating device is utilized to provide at least a first heating beam 34 and a second heating beam 36 with different energy density on the front surface 14 of the semiconductor substrate 12, such as the aforementioned source/drain extension doping region or source/drain doping region. In this embodiment, the first heating beam 34 and the second heating beam 36 are preferably laser beams, and the first heating beam 34 is provided to heat the front surface 14 of the semiconductor substrate 12 according to a first incident angle a while the second heating beam 36 is provided to heat the front surface 14 of the semiconductor substrate 12 according to a second incident angle b. Despite the front surface 14 of the semiconductor substrate 12 is heated by both the first heating beam 34 and the second heating beam 36, the first incident angle a and the second incident angle b could be the same or different according to the demand of the process.

Preferably, a millisecond anneal process is conducted by using the first heating beam 34 to heat the front surface 14 of the semiconductor substrate 12 and a rapid thermal anneal process is conducted by using the second heating beam 36 to heat the front surface 14 of the semiconductor substrate 12, in which the temperature of the millisecond anneal process is between 1000° C. to 1350° C. and the duration of the millisecond anneal process is between 0.1 ms to 20 ms, and the temperature of the rapid thermal anneal process is between 900° C. to 1100° C. and the duration of the rapid thermal anneal process is between 1.5 ms to 100 ms. As the millisecond anneal process carried out by the first heating beam 34 involves higher temperature and shorter duration, a local intensive heating is preferably conducted by this anneal on the front surface 14 of the semiconductor substrate 12. The rapid thermal anneal process carried out by the second heating beam 36 involves lower temperature and longer duration, hence a local pre-heating is achieved on the front surface 14 of the semiconductor substrate 12. Moreover, by using the same laser generating device to generate both the first heating beam 34 and the second heating beam 36 for performing the millisecond anneal and rapid thermal anneal, this embodiment also eliminates the need to switch between two different thermal processing equipments, thereby reducing the cycle time of the overall fabrication substantially.

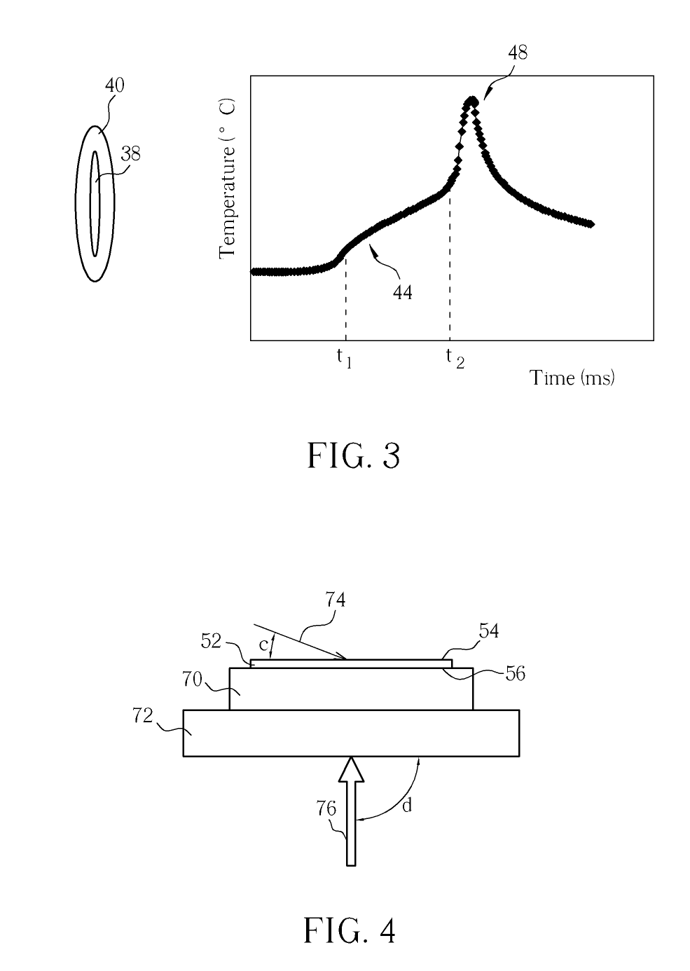

Referring to FIG. 3, FIG. 3 illustrates the spots generated by two heating beams heating the surface of the semiconductor substrate 12 simultaneously and a relational diagram between temperature and time. As shown in the left portion of FIG. 3, two spots are preferably formed on the front surface 14 of the semiconductor substrate 12 by the first heating beam 34 and the second heating beam 36, including a slightly smaller first spot 38 generated by the first heating beam 34 and a larger second spot 40 generated by the second heating beam 36. Despite the first spot 38 is completely overlapped by the second spot 40 in this embodiment, the position of the spots 38/40 could be adjusted by changing the direction of the two heating beams, such that the first spot 38 could only be partially overlapped by the second spot 40 or not overlapped by the second spot 40 at all.

As shown in the right portion of FIG. 3, after heating the semiconductor substrate 12 at time t1 with the front edge of the second heating beam 36 as the scanning apparatus is in motion, the temperature of the semiconductor substrate 12 would slowly rise to a first peak 44 as the substrate 12 is treated by the second heating beam 36, and after heating the semiconductor substrate 12 at time t2 with the front edge of the first heating beam 34, the temperature of the semiconductor substrate 12 would rise quickly and reaching a much steeper second peak 48, and cools down thereafter. It should be noted that the relational diagram shown on the right portion of FIG. 3 is preferably generated by the overlapping of the two spots 38/40 on the left. If the first spot 38 is only partially overlapped by the second spot 40 or not overlapped by the second spot 40 at all, the position of the second peak 48 would shift slightly forward or backward according to the overlapping condition of the two spots.

After the semiconductor substrate 12 is heated by the first heating beam 34 and the second heating beam 36, a source/drain extension region 26 or a source/drain region 28 is formed in the semiconductor substrate 12 of FIG. 2 to complete the thermal process of the first embodiment of the present invention.

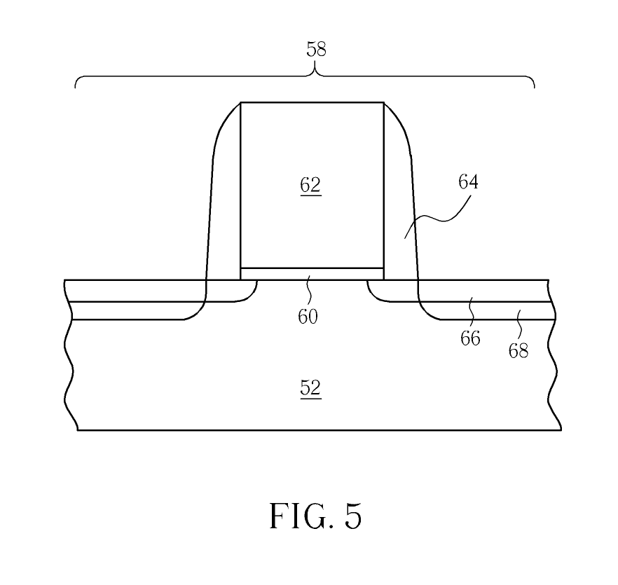

Referring to FIGS. 4-5, FIG. 4 illustrates a perspective view of performing a thermal process on a semiconductor substrate 52 according to a second embodiment of the present invention, and FIG. 5 illustrates a perspective view of a MOS transistor region of the semiconductor substrate 52. As shown in the figures, a semiconductor substrate 52, such as a silicon wafer ready to be heated is provided. The semiconductor substrate 52 has a front surface 54 and a back surface 56, in which a MOS transistor region 58 is defined on the front surface 54. Structures including a gate dielectric layer 60, a gate 62, and a spacer 64 are preferably formed on the front surface 54 of the semiconductor substrate 52. Moreover, at least one ion implantation is conducted to form a source/drain extension doping region (not shown) adjacent to two sides of the gate 62 in the semiconductor substrate 52 or a source/drain doping region (not shown) adjacent to two sides of the spacer 64 in the semiconductor substrate 52.

The semiconductor substrate 52 is then placed on a scanning apparatus 70, which is preferably situated on top of a supporting stage 72. After turning on the scanning apparatus 70 and putting the semiconductor substrate 52 in motion, a thermal processing equipment (not shown), such as a laser generating device is utilized to provide at least a first heating beam 74 and a second heating beam 76 with different energy density on the front surface 54 of the semiconductor substrate 52, such as the aforementioned source/drain extension doping region or source/drain doping region. In this embodiment, the first heating beam 74 and the second heating beam 76 are preferably laser beams, and the first heating beam 74 is provided to heat the front surface 54 of the semiconductor substrate 52 according to a first incident angle c while the second heating beam 76 is provided to heat the back surface 56 of the semiconductor substrate 52 according to a second incident angle d. Preferably, the first incident angle c and the second incident angle d could be the same or different according to the demand of the process.

Similar to the first embodiment, a millisecond anneal process is conducted by using the first heating beam 74 to heat the front surface 54 of the semiconductor substrate 52 and a rapid thermal anneal process is conducted by using the second heating beam 76 to heat the back surface 56 of the semiconductor substrate 52, in which the temperature of the millisecond anneal process is between 900° C. to 1350° C. and the duration of the millisecond anneal process is between 0.1 ms to 20 ms, and the temperature of the rapid thermal anneal process is between 900° C. to 1100° C. and the duration of the rapid thermal anneal process is between 1.5 ms to 100 ms. Moreover, the spots generated by the first heating beam 74 and the second heating beam 76 on the semiconductor substrate 52 could be overlapped to each other, at least partially overlapping each other, or not overlapping each other at all. After the semiconductor substrate 52 is heated by the first heating beam 74 and the second heating beam 76, a source/drain extension region 66 or a source/drain region 68 is formed in the semiconductor substrate 52 of FIG. 5.

By using the millisecond anneal process to partially heat the front surface of the semiconductor substrate and using the rapid thermal anneal process to perform an overall heating on the back side of the semiconductor substrate, the present embodiment not only eliminates the need of switching between two different thermal processing equipments, but also improving the patterning effect caused by the conventional front side heating substantially.

It should also be noted that the aforementioned two embodiments, including the first embodiment of using the first heating beam and the second heating beam to heat the front surface of the semiconductor substrate simultaneously and the second embodiment of using the first heating beam and the second heating beam to heat the front and back surface of the semiconductor substrate respectively, could be performed after any ion implantation for activating the doping regions. For instance, either one of the above two embodiments could be applied in the following scenarios: after implanting dopants used to form a source/drain extension region, performing either one of the above two embodiments to activate a source/drain extension region; or first implanting dopants used to forming a source/drain extension region, performing one single rapid thermal anneal process or laser anneal process, implanting dopants used to activate a source/drain region, and performing either one of the above two embodiments thereafter to form a source/drain region. Despite the thermal process disclosed in the present invention is preferably applied to doping regions such as the activation of the source/drain extension region or the source/drain region, the above embodiments could be applied to any doping regions requiring two or more thermal treatments, including growth, anneal, diffusion of thin oxide layers, formation of salicides, or even fabrication of polysilicon semiconductor layer in thin film transistors, which are all within the scope of the present invention.

Those skilled in the art will readily observe that numerous modifications and alterations of the device and method may be made while retaining the teachings of the invention.

What is claimed is:

1. A thermal process, comprising:
providing a semiconductor substrate ready to be heated; and
utilizing at least a first heating beam and a second heating beam with different energy density to heat the semiconductor substrate simultaneously.

2. The thermal process of claim 1, wherein the semiconductor substrate comprises a silicon wafer.

3. The thermal process of claim 1, further comprising utilizing the first heating beam to perform a millisecond anneal process on a front surface of the semiconductor substrate and utilizing the second heating beam to perform a rapid thermal anneal process on a back surface of the semiconductor substrate.

4. The thermal process of claim 3, wherein the temperature of the millisecond anneal process is between 1000° C. to 1350° C.

5. The thermal process of claim 3, wherein the duration of the millisecond anneal process is between 0.1 ms to 20 ms.

6. The thermal process of claim 3, wherein the temperature of the rapid thermal anneal process is between 900° C. to 1100° C.

7. The thermal process of claim 3, wherein the duration of the rapid thermal anneal process is between 1.5 ms to 100 ms.

8. The thermal process of claim 3, further comprising utilizing the first heating beam to heat the front surface of the semiconductor substrate according to a first incident angle and utilizing the second heating beam to heat the back surface of the semiconductor substrate according to a second incident angle.

9. The thermal process of claim 8, wherein the first incident angle is different from the second incident angle.

10. The thermal process of claim 1, further comprising utilizing the first heating beam to perform a millisecond anneal process on a front surface of the semiconductor substrate and utilizing the second heating beam to perform a rapid thermal anneal process on the front surface of the semiconductor substrate.

11. The thermal process of claim 10, wherein the temperature of the millisecond anneal process is between 1000° C. to 1350° C.

12. The thermal process of claim 10, wherein the duration of the millisecond anneal process is between 0.1 ms to 20 ms.

13. The thermal process of claim 10, wherein the temperature of the rapid thermal anneal process is between 900° C. to 1100° C.

14. The thermal process of claim 10, wherein the duration of the rapid thermal anneal process is between 1.5 ms to 100 ms.

15. The thermal process of claim 10, further comprising utilizing the first heating beam to heat the front surface of the semiconductor substrate according to a first incident angle and utilizing the second heating beam to heat the front surface of the semiconductor substrate according to a second incident angle.

16. The thermal process of claim 15, wherein the first incident angle is different from the second incident angle.

17. The thermal process of claim 3, wherein the region spotted by the first heating beam on the semiconductor substrate not overlapping the region spotted by the second heating beam on the semiconductor substrate.

18. The thermal process or claim 3, wherein the region spotted by the first heating beam on the semiconductor substrate partially overlapping the region spotted by the second heating beam on the semiconductor substrate.

19. The thermal process of claim 1, further comprising forming a gate on a front surface of the semiconductor substrate, a source/drain extension region adjacent to two sides of the gate in the semiconductor substrate, a spacer surrounding the gate, and a source/drain region adjacent to two sides of the spacer in the semiconductor substrate.

20. The thermal process of claim 19, further comprising utilizing the first heating beam and the second heating beam to heat the semiconductor substrate for forming the source/drain extension region or the source/drain region.
